(19) United States
(12) Patent Application Publication
(10) Pub. No.: US 2018/0053787 A1
(43) Pub. Date: Feb. 22, 2018

(54) DISPLAY DEVICE AND MANUFACTURING METHOD THEREOF

(71) Applicant: Samsung Display Co., Ltd, Yongin-si (KR)

(72) Inventors: Tae Woo LIM, Yongin-si (KR); Seong Gyu KWON, Suwon-si (KR); Choi Sang PARK, Suwon-si (KR)

(21) Appl. No.: 15/470,418

(22) Filed: Mar. 27, 2017

(30) Foreign Application Priority Data
Aug. 17, 2016 (KR) 10-2016-0104285

(51) Int. Cl. H01L 27/12; G02F 1/1368; G02F 1/1333; G02F 1/1362; G02F 1/1341

(52) U.S. Cl. CPC H01L 27/124; H01L 27/1259; H01L 27/1248; G02F 2201/123; G02F 1/133377; G02F 1/136286; G02F 1/1341; G02F 1/1368

(57) ABSTRACT

Disclosed is a display device and a manufacturing method thereof. The display device includes: a substrate including a display area and a peripheral area; a thin film transistor disposed on the display area of the substrate; a first electrode connected to the thin film transistor; a roof layer disposed on the first electrode and separated from the first electrode with a microcavity therebetween; an encapsulation layer disposed on the roof layer; a pad disposed on the peripheral area of the substrate; a pad assistant overlapping the pad and connected to the pad; and a dummy pattern neighboring the pad assistant and made of a transparent conductive material.

### RELATED APPLICATIONS

This application claims priority to and the benefit of Korean Patent Application No. 10-2016-0104285 filed in the Korean Intellectual Property Office on Aug. 17, 2016, the entire contents of which are incorporated herein by reference.

### BACKGROUND

### 1. Field

The described technology relates generally to a display device and a manufacturing method thereof.

### 2. Description of the Related Art

A liquid crystal display, which is presently one of the most widely used flat panel displays, includes two substrates with field generating electrodes such as a pixel electrode and a common electrode, and a liquid crystal layer interposed therebetween. An amount of transmitted light is controlled by determining alignment of liquid crystal molecules of the liquid crystal layer through application of voltages to the field generating electrodes to display an image.

The two sheets of display panels configuring the liquid crystal display may include a thin film transistor array panel and an opposing display panel. A gate line transferring a gate signal and a data line transferring a data signal are formed to cross each other, and a thin film transistor connected with the gate line and the data line, a pixel electrode connected with the thin film transistor, and the like may be formed on the thin film transistor array panel. A light blocking member, a color filter, a common electrode, and the like may be formed on the opposing display panel. In some cases, the light blocking member, the color filter, and the common electrode may be formed on the thin film transistor array panel.

However, in a liquid crystal display in the related art, the two sheets of substrates are necessarily used and respective constituent elements are formed on the two sheets of substrates, which results in problems that the display device is heavy and thick, has a high cost, and has a long processing time.

The above information disclosed in this Background section is only for enhancement of understanding of the background of the described technology and therefore it may contain information that does not form the prior art that is already known in this country to a person of ordinary skill in the art.

### SUMMARY

Embodiments of the present inventive concept have been made in an effort to provide a display device having advantages of reduced weight, thickness, cost, and processing time by manufacturing the display device using one substrate, and a manufacturing method thereof.

When the display device is manufactured by using one substrate, an encapsulation layer for sealing a liquid crystal layer may be generated. A pad portion may be generated while not being covered by the encapsulation layer so that the pad portion may be connected to an external terminal.

Therefore, a process for removing the encapsulation layer disposed in the peripheral area of the substrate may be performed after the encapsulation layer is generated on the substrate. In this instance, part of the encapsulation layer may not be removed but may remain. The encapsulation layer remaining on the peripheral area of the substrate is considered a foreign particle in that it will deteriorate reliability of the display device.

The described technology has been made in an effort to provide a display device which does not allow the encapsulation layer to remain on the peripheral area of the substrate, and a manufacturing method thereof.

An exemplary embodiment provides a display device including: a substrate including a display area and a peripheral area; a thin film transistor disposed on the display area of the substrate; a first electrode connected to the thin film transistor; a roof layer disposed on the first electrode and separated from the first electrode with a microcavity therebetween; an encapsulation layer disposed on the roof layer; a pad disposed on the peripheral area of the substrate; a pad assistant overlapping the pad and connected to the pad; and a dummy pattern neighboring the pad assistant and made of a transparent conductive material.

The dummy pattern may be disposed on a same layer as the pad assistant and the first electrode, and may be made of a same material.

The dummy pattern may be made of an indium-tin oxide or an indium-zinc oxide.

The pad and the pad assistant may extend in a first direction, and the dummy pattern may include a first dummy pattern neighboring the pad assistant in the first direction.

The dummy pattern may be equal to or greater than 20 μm wide.

The dummy pattern may be floated.

The dummy pattern may be circular or polygonal in a plane view.

The dummy pattern may further include a second dummy pattern neighboring the pad assistant in a second direction that is perpendicular to the first direction.

A plurality of pads may be disposed on the peripheral area of the substrate, and the second dummy pattern may be disposed between two neighboring pads from among the plurality of pads.

The pad assistant and the dummy pattern may be integrally formed.

Another embodiment provides a method for manufacturing a display device, including: generating a thin film transistor on a display area of a substrate including the display area and a peripheral area; generating a pad on the peripheral area of the substrate; generating a first electrode to be connected to the thin film transistor; generating a pad assistant to be connected to the pad; generating a dummy pattern with a transparent conductive material to neighbor the pad assistant; generating a sacrificial layer on the first electrode, the pad assistant, and the dummy pattern; generating an insulating layer on the sacrificial layer; generating a roof layer on the insulating layer; generating a microcavity between the first electrode and the insulating layer by removing the sacrificial layer, and generating a dummy microcavity between the pad assistant and the insulating layer and between the dummy pattern and the insulating layer; generating an encapsulation layer on the roof layer; and removing the encapsulation layer and the insulating layer disposed on the peripheral area of the substrate.

The method may further include generating an injection hole for exposing at least part of the dummy microcavity by patterning the insulating layer, wherein the injection hole overlaps the pad assistant and the dummy pattern.

The dummy pattern may be disposed in a same layer as the pad assistant and the first electrode and is made of a same material, and the dummy pattern may be made of an indium-tin oxide or an indium-zinc oxide.

The pad and the pad assistant may extend in a first direction, and the dummy pattern may include a first dummy pattern neighboring the pad assistant in the first direction.

The dummy pattern may be equal to or greater than 20 μm wide.

The dummy pattern may be floated.

The dummy pattern may be circular or polygonal in a plane view.

The dummy pattern may further include a second dummy pattern neighboring the pad assistant in a second direction that is perpendicular to the first direction.

A plurality of pads may be disposed on the peripheral area of the substrate, and the second dummy pattern may be disposed between two neighboring pads from among the plurality of pads.

The pad assistant and the dummy pattern may be integrally formed.

According to exemplary embodiments, the encapsulation layer may not remain on the peripheral area of the substrate.

### BRIEF DESCRIPTION OF THE DRAWINGS

FIG. 1 shows a top plan view of a display device according to an exemplary embodiment.

FIG. 2 shows a top plan view of one pixel disposed in a display area of a display device according to an exemplary embodiment.

FIG. 3 shows a cross-sectional view of a display device with respect to a line of FIG. 2 according to an exemplary embodiment.

FIG. 4 shows a cross-sectional view of a display device with respect to a line IV-IV of FIG. 2 according to an exemplary embodiment.

FIG. 5 shows a top plan view of a peripheral area of a display device according to an exemplary embodiment.

FIG. 6 shows a cross-sectional view of a display device with respect to a line VI-VI of FIG. 5 according to an exemplary embodiment.

FIG. 7 shows a top plan view of a peripheral area of a display device according to an exemplary embodiment.

FIG. 8 shows a top plan view of a peripheral area of a display device according to an exemplary embodiment.

FIG. 9 shows a top plan view of a peripheral area of a display device according to an exemplary embodiment.

FIG. 10, 11, 12, 13, 14, 15, 16, 17, 18, 19, 20, 21, 22, 23, 24, and FIG. 25 show processing cross-sectional views of a method for manufacturing a display device according to an exemplary embodiment.

### DETAILED DESCRIPTION

The present inventive concept will be described more fully hereinafter with reference to the accompanying drawings, in which exemplary embodiments of the invention are shown. As those skilled in the art would realize, the described embodiments may be modified in various different ways, all without departing from the spirit or scope of the present inventive concept.

To clearly describe the present inventive concept, portions which do not relate to the description are omitted, and like reference numerals designate like elements throughout the specification.

The size and thickness of each component shown in the drawings are arbitrarily shown for better understanding and ease of description, but the present inventive concept is not limited thereto. In the drawings, the thickness of layers, films, panels, regions, etc., are exaggerated for clarity. For better understanding and ease of description, the thickness of some layers and areas is exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

The phrase “on a plane” means viewing the object portion from the top, and the phrase “on a cross-section” means viewing a cross-section of which the object portion is vertically cut from the side.

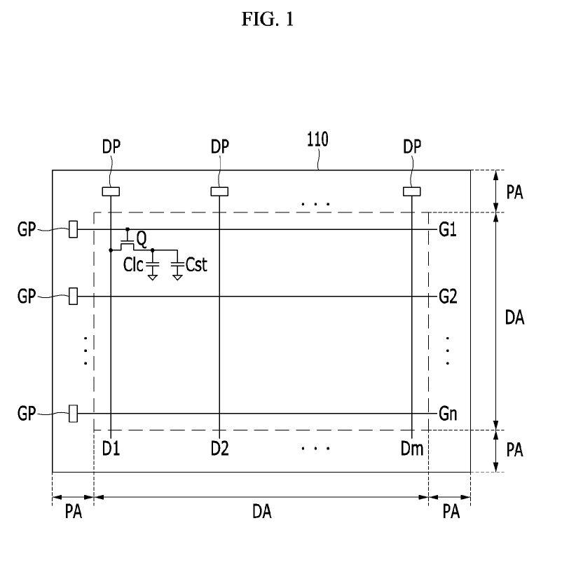

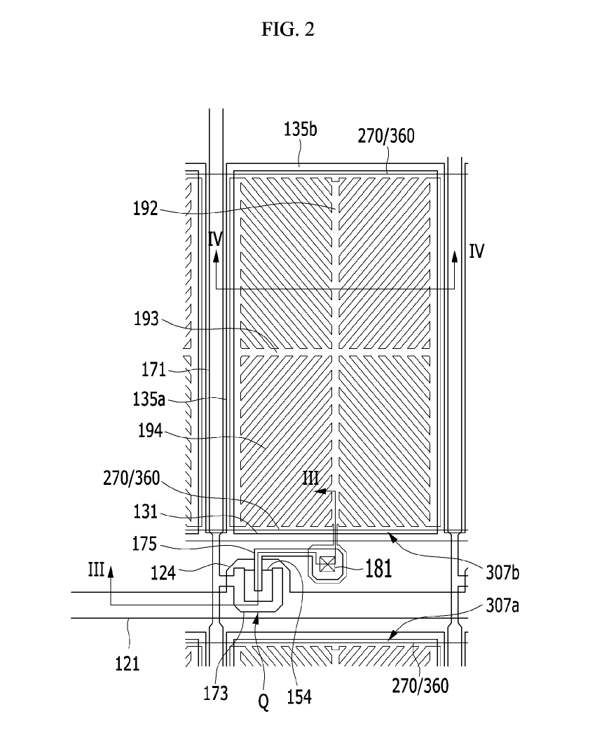

A display device according to an exemplary embodiment will now be described with reference to FIG. 1.

FIG. 1 shows a top plan view of a display device according to an exemplary embodiment.

The display device includes a substrate 110 made of a material such as glass or plastic.

The substrate 110 is divided into a display area (DA) and a peripheral area (PA). The display area (DA) is disposed in a center portion of the substrate 110, and the peripheral area (PA) is disposed to surround the display area (DA). The display area (DA) is a region for displaying an image, and drivers for transmitting driving signals to display an image in the display area (DA) are disposed in the peripheral area (PA).

In the display area (DA), a plurality of gate lines (G1, G2 . . . , Gn) are disposed in parallel with each other, and a plurality of data lines (D1 . . . , Dm) are disposed in parallel with each other. The gate lines (G1, G2 . . . , Gn) and the data lines (D1, D2 . . . , Dm) are insulated from each other, and cross each other to define a plurality of pixels.

A thin film transistor Q, a liquid crystal capacitor Clc, and a storage capacitor Cst are disposed on each pixel. The thin film transistor Q includes a control terminal connected to one of the gate lines (G1, G2 . . . , Gn), an input terminal connected to one of the data line (D1, D2 . . . , Dm), and an output terminal connected to a first terminal of the liquid crystal capacitor Clc and a first terminal of the storage capacitor Cst. The liquid crystal capacitor Clc includes a second terminal for receiving a common voltage, and the storage capacitor Cst includes a second terminal for receiving a reference voltage.

The gate lines (G1, G2 . . . , Gn) and the data lines (D1, D2 . . . , Dm) extend to the peripheral area (PA). In the peripheral area (PA), a gate pad portion (GP) connected to the gate lines (G1, G2 . . . , Gn) is disposed and a data pad portion (DP) connected to the data lines (D1, D2 . . . , Dm) is disposed. The gate pad portion (GP) may be connected to an external terminal, and it receives a gate signal from a gate driver and transmits the same to the gate lines (G1, G2 . . . , Gn). The data pad portion (DP) may be connected to an external terminal, and it receives a data signal from a data driver and transmits the same to the data lines (D1, D2 . . . , Dm).

In FIG. 1, the gate pad portion (GP) is shown to be disposed on a left edge of the display area (DA), but the present inventive concept is not limited thereto, and the gate pad portion (GP) may be disposed at various positions. Further, the gate pad portion (GP) may be disposed on respective edges of the display area (DA).

In FIG. 1, the data pad portion (DP) is shown to be disposed on an upper edge of the display area (DA), but the present inventive concept is not restricted thereto, and the data pad portion (DP) may be disposed at various positions. Further, the data pad portion (DP) may be disposed on the respective edges of the display area (DA).

One pixel disposed in the display area of the display device according to an exemplary embodiment will now be described with reference to FIG. 2 to FIG. 4.

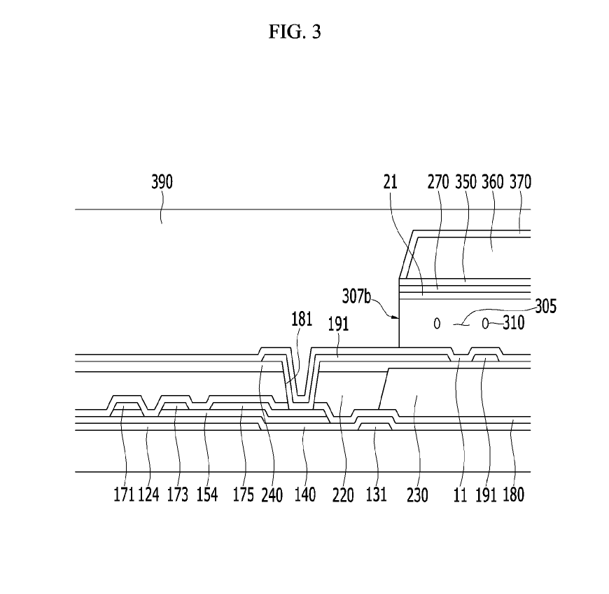

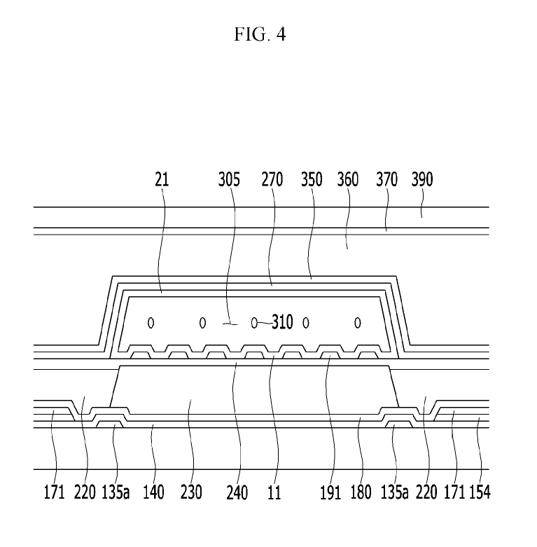

FIG. 2 shows a top plan view of one pixel disposed in a display area of a display device according to an exemplary embodiment, FIG. 3 shows a cross-sectional view of a display device with respect to a line III-III of FIG. 2 according to an exemplary embodiment, and FIG. 4 shows a cross-sectional view of a display device with respect to a line IV-IV of FIG. 2 according to an exemplary embodiment.

Referring to FIG. 2 to FIG. 4, a gate line 121 and a gate electrode 124 protruding from the gate line 121 are disposed on the substrate 110.

The gate line 121 substantially extends in a horizontal direction and transmits the gate signal. The gate electrode 124 protrudes upward from the gate line 121 in a plane view. The present inventive concept is not limited thereto, and a protruding shape of the gate electrode 124 is modifiable in various ways. The gate electrode 124 may not protrude from the gate line 121, but may be disposed on the gate line 121. The gate line 121 and the gate electrode 124 are disposed in the display area (DA), and the gate line 121 extends to the peripheral area (PA).

A reference voltage line 131 and storage electrodes 135a and 135b protruding from the reference voltage line 131 may further be disposed on the substrate 110. The reference voltage line 131 substantially extends in parallel to the gate line 121, and is separated from the gate line 121. A constant voltage may be applied to the reference voltage line 131. The storage electrodes 135a and 135b include a pair of first storage electrodes 135a substantially extending to be perpendicular to the reference voltage line 131 and a second storage electrode 135b for connecting the pair of first storage electrodes 135a. The reference voltage line 131 and the storage electrodes 135a and 135b may surround a pixel electrode 191 to be described.

A gate insulating layer 140 is disposed on the gate line 121, the gate electrode 124, the reference voltage line 131, and the storage electrodes 135a and 135b. The gate insulating layer 140 may be made of an inorganic insulating material such as a silicon nitride (SiNx) or a silicon oxide (SiOx). The gate insulating layer 140 may also be made of a single layer or multiple layers.

A semiconductor 154 is disposed on the gate insulating layer 140. The semiconductor 154 may be disposed on the gate electrode 124. The semiconductor 154 may be made of amorphous silicon, polycrystalline silicon, or a metal oxide. An ohmic contact (not shown) may further be disposed on the semiconductor 154. The ohmic contact may be made of a material such as a silicide or n+ hydrogenated amorphous silicon doped with an n-type impurity at a high concentration.

A data line 171, a source electrode 173, and a drain electrode 175 are disposed on the semiconductor 154 and the gate insulating layer 140.

The data line 171 transmits a data signal and substantially extends in the vertical direction to cross the gate line 121 and the reference voltage line 131. The source electrode 173 protrudes over the gate electrode 124 from the data line 171, and it may be bent in a U shape. The drain electrode 175 includes a wide first end portion and a bar-type second end portion. The wide end portion of the drain electrode 175 overlaps the pixel electrode 191. The bar-type end portion of the drain electrode 175 is partially surrounded by the source electrode 173. The present inventive concept is not limited thereto, and the source electrode 173 and the drain electrode 175 may have various different shapes. The data line 171, the source electrode 173, and the drain electrode 175 are disposed in the display area (DA), and the data line 171 extends to the peripheral area (PA).

The gate electrode 124, the source electrode 173, and the drain electrode 175 form a thin film transistor (TFT) Q with the semiconductor 154. In this instance, the thin film transistor Q includes a channel generated on the semiconductor 154 between the source electrode 173 and the drain electrode 175.

A passivation layer 180 is disposed on the data line 171, the source electrode 173, the drain electrode 175, the semiconductor 154 disposed between the source electrode 173 and the drain electrode 175, and a data pad 177. The passivation layer 180 may be made of an organic insulating material or an inorganic insulating material, and it may be made of a single layer or multiple layers.

A color filter 230 is disposed in each pixel on the passivation layer 180.

Each color filter 230 may display one of the three primary colors of red, green, and blue. The color filter 230 is not limited to the three primary colors of red, green, and blue, and it may display cyan, magenta, yellow, or white-based colors.

A light blocking member 220 is disposed in a region between the neighboring color filters 230. The light blocking member 220 is disposed on a border portion of the pixel, and may overlap the gate line 121, the data line 171, and the thin film transistor Q to prevent light leakage. The present inventive concept is not restricted thereto, and the light blocking member 220 may overlap the gate line 121 and the thin film transistor Q and not the data line 171. In this instance, the portion overlapping the data line 171 may overlap the color filter 230 to prevent the light leakage. The color filter 230 may overlap the light blocking member 220 in a predetermined region.

A first insulating layer 240 may further be disposed on the color filter 230 and the light blocking member 220. The first insulating layer 240 may be made of an organic insulating material, and may planarize the upper sides of the color filter 230 and the light blocking member 220. The first insulating layer 240 may be made of double layers including a layer of an organic insulating material and a layer of an inorganic insulating material. Further, the first insulating layer 240 may be omitted.

A contact hole 181 overlapping at least part of the drain electrode 175 is generated on the first insulating layer 240, the light blocking member 220, and the passivation layer 180. The contact hole 181 may expose the wide end portion of the drain electrode 175.

A pixel electrode 191 is generated on the first insulating layer 240. The pixel electrode 191 may be made of a transparent conductive material such as an indium-tin oxide (ITO) or an indium-zinc oxide (IZO). The pixel electrode 191 is connected to the drain electrode 175 through the contact hole 181. Therefore, when the thin film transistor Q is turned on, the pixel electrode 191 receives a data voltage through the drain electrode 175.

The pixel electrode 191 has a quadrangular shape, and the pixel electrode 191 includes a horizontal stem 193 and a vertical stem 192 crossing each other, and a fine branch 194 extending therefrom. The pixel electrode 191 is divided into four sub-regions by the horizontal stem 193 and the vertical stem 192. The fine branch 194 extends from the horizontal stem 193 and the vertical stem 192 in an oblique manner, and the extending direction may form an angle of about 45 degrees or 135 degrees with respect to the gate line 121 or the horizontal stem 193. Further, fine branches 194 of two neighboring sub-regions may extend to cross each other in an orthogonal manner.

In the present exemplary embodiment, the pixel electrode 191 may further include an external stem surrounding the pixel.

The above-described disposal form of the pixel, the structure of the thin film transistor, and the shape of the pixel electrode are just one example, and the present inventive concept is not limited thereto, as numerous variations are possible. For example, one pixel may include a plurality of subpixels, and a different voltage may be applied to each subpixel. For this purpose, a plurality of thin film transistors may be generated on one pixel.

A common electrode 270 is generated on the pixel electrode 191 and is separated from the pixel electrode 191 with a predetermined distance therebetween.

A microcavity 305 is generated between the pixel electrode 191 and the common electrode 270. That is, the microcavity 305 is surrounded by the pixel electrode 191 and the common electrode 270. The common electrode 270 may extend in the row direction. The common electrode 270 covers part of an upper side and a lateral side of the microcavity 305. A size of the microcavity 305 may be changed in various ways according to a size and a resolution of the display device.

It is shown that a plurality of microcavities 305 are disposed on the substrate 110, and one microcavity 305 corresponds to one pixel. The present inventive concept is not limited thereto, the microcavity 305 may correspond to a plurality of pixels, and the microcavity 305 may correspond to some of the pixels. When one pixel is configured with two subpixels, the microcavity 305 may correspond to one subpixel. Further, the microcavity 305 may correspond to two subpixels neighboring each other.

The common electrode 270 may be made of a transparent conductive material such as an indium-tin oxide (ITO) or an indium-zinc oxide (IZO). The common electrode 270 may receive a predetermined voltage, and an electric field may be generated between the pixel electrode 191 and the common electrode 270.

Alignment layers 11 and 21 are generated over the pixel electrode 191 and below the common electrode 270.

The alignment layers 11 and 21 include a first alignment layer 11 and a second alignment layer 21. The first alignment layer 11 and the second alignment layer 21 may be vertical alignment layers, and may be made of an aligning material such as a polyamic acid, a polysiloxane, or a polyimide. The first and second alignment layers 11 and 21 may be connected on the lateral wall of the edge of the microcavity 305.

The first alignment layer 11 is generated on the pixel electrode 191. The first alignment layer 11 may be generated just over the first insulating layer 240 that is not covered by the pixel electrode 191.

The second alignment layer 21 is generated below the common electrode 270 to face the first alignment layer 11.

A liquid crystal layer of liquid crystal molecules 310 is generated in the microcavity 305 disposed between the pixel electrode 191 and the common electrode 270. The liquid crystal molecules 310 may have negative dielectric anisotropy, and may be disposed to be perpendicular to the substrate 110 while no electric field is applied. That is, a vertical alignment is allowable.

The pixel electrode 191 to which a data voltage is applied generates the electric field together with the common electrode 270 to determine the direction of the liquid crystal molecules 310 disposed in the microcavity 305 between the two electrodes 191 and 270. Luminance of light passing through the liquid crystal layer becomes different according to the determined direction of the liquid crystal molecules 310.

A second insulating layer 350 may be further generated on the common electrode 270. The second insulating layer 350 may be made of an inorganic insulating material such as a silicon nitride (SiNx) or a silicon oxide (SiOx).

A roof layer 360 is generated on the second insulating layer 350. The roof layer 360 may be made of an organic material or an inorganic material. The roof layer 360 may be made of a single layer or multiple layers. The roof layer 360 may extend in the row direction. The roof layer 360 covers part of an upper side and a lateral side of the microcavity 305. The roof layer 360 is cured by a curing process to maintain the shape of the microcavity 305. The roof layer 360 is generated to be separated from the pixel electrode 191 with the microcavity 305 therebetween.

In the drawing, the color filter 230 is shown to be disposed below the microcavity 305, but the present inventive concept is not limited thereto. The position of the color filter 230 is changeable. For example, the roof layer 360 may be made of a color filter material, and in this instance, the color filter 230 is disposed above the microcavity 305.

The common electrode 270 and the roof layer 360 do not cover part of the lateral side of the edge of the microcavity 305, and portions of the microcavity 305 that are not covered by the common electrode 270 and the roof layer 360 are referred to as injection holes 307a and 307b. The injection holes 307a and 307b include a first injection hole 307a disposed on the lateral side of the first edge of the microcavity 305 and a second injection hole 307b disposed on the lateral side of the second edge of the microcavity 305. The first edge faces the second edge, and for example, the first edge may be an upper edge of the microcavity 305 and the second edge may be a lower edge of the microcavity 305 in a plane view. The microcavity 305 is exposed by the injection holes 307a and 307b during the process for manufacturing a display device, so an aligning agent or a liquid crystal material may be injected into the microcavity 305 through the injection holes 307a and 307b.

A third insulating layer 370 may be further generated on the roof layer 360. The third insulating layer 370 may be made of an inorganic insulating material such as a silicon nitride (SiNx) or a silicon oxide (SiOx). The third insulating layer 370 may be generated to cover an upper side and/or a lateral side of the roof layer 360. The third insulating layer 370 protects the roof layer 360 made of an organic material and it may be omitted depending on the case.

An encapsulation layer 390 is generated on the third insulating layer 370. The encapsulation layer 390 covers injection holes 307a and 307b disposed on the edge of the microcavity 305. That is, the encapsulation layer 390 may seal the microcavity 305 so that the liquid crystal molecules 310 in the microcavity 305 may not go out. The encapsulation layer 390 contacts the liquid crystal molecules 310 so it is desirable to manufacture the encapsulation layer 390 with a material that does not react with the liquid crystal molecule 310. For example, the encapsulation layer 390 may be made of perylene.

The encapsulation layer 390 may be configured to be multiple layers such as double layers or triple layers. The double layers are formed with two layers made of different materials. The triple layers are configured with three layers, and materials of neighboring layers are different from each other. For example, the encapsulation layer 390 may include a layer made of an organic insulating material and a layer made of an inorganic insulating material.

Although not shown, a polarizer may further be generated on an upper/lower side of the display device. The polarizer may include a first polarizer and a second polarizer. The first polarizer may be attached to the lower side of the substrate 110, and the second polarizer may be attached to the upper side of the encapsulation layer 390.

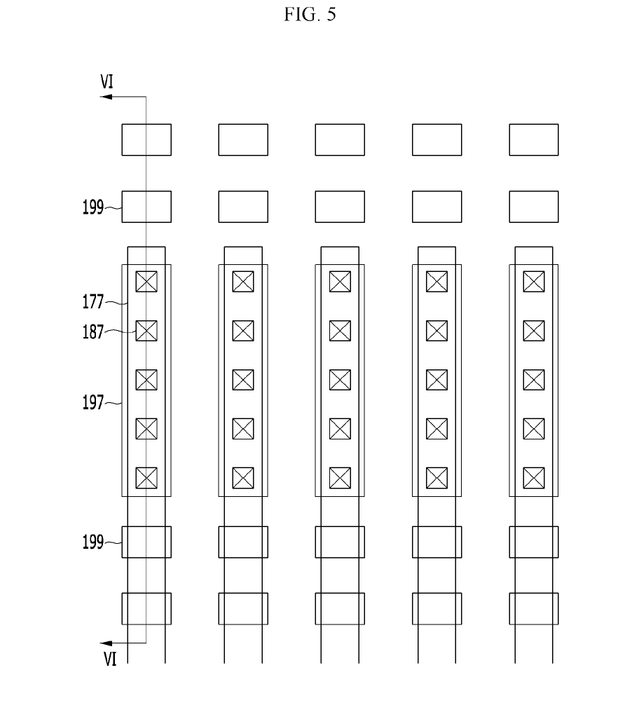

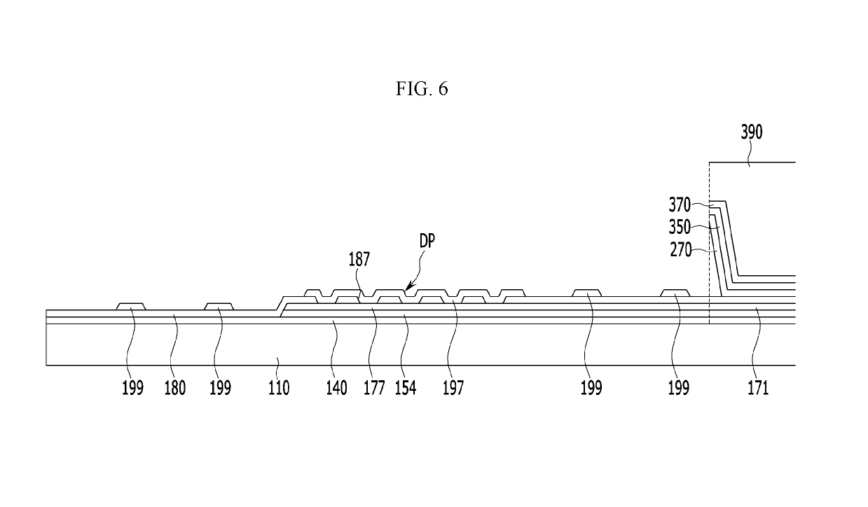

A peripheral area of a display device according to an exemplary embodiment will now be described with reference to FIG. 5 and FIG. 6.

FIG. 5 shows a top plan view of a peripheral area of a display device according to an exemplary embodiment, and FIG. 6 shows a cross-sectional view of a display device with respect to a line VI-VI of FIG. 5 according to an exemplary embodiment.

In a like manner as of the display area (DA), a gate insulating layer 140 is disposed on the peripheral area (PA) of the substrate 110.

A data pad 177 is disposed on the gate insulating layer 140. As described above, the data line 171 extends to the peripheral area (PA), and the data pad 177 is connected to the data line 171. The data pad 177 may be generated to have a bar shape extending in a direction in which the data line 171 extends in the plane view. For example, the data line 171 and the data pad 177 may substantially extend in the vertical direction. The data pad 177 may be made of the same material as the data line 171, the source electrode 173, and the drain electrode 175, and may be disposed on a same layer thereof.

A passivation layer 180 is disposed on the data pad 177. The color filter 230, the light blocking member 220, and the first insulating layer 240 are shown to not be disposed on the peripheral area (PA) of the substrate 110. The present exemplary embodiment is not limited thereto, and the color filter 230, the light blocking member 220, and the first insulating layer 240 may be disposed on part of the peripheral area (PA) of the substrate 110.

A contact hole 187 overlapping at least part of the data pad 177 is generated on the passivation layer 180. One data pad 177 may overlap a plurality of contact holes 187.

A data pad assistant 197 is disposed on the passivation layer 180. The data pad assistant 197 may be generated to have a bar shape extending in the direction in which the data pad 177 extends in the plane view. For example, the data pad assistant 197 may substantially extend in the vertical direction.

The data pad assistant 197 is connected to the data pad 177 through the contact hole 187. The data pad assistant 197 may be made of the same material as the pixel electrode 191 and may be disposed on the same layer thereof. The data pad 177 and the data pad assistant 197 are stacked to form a data pad portion (DP).

A dummy pattern 199 is disposed to neighbor the data pad assistant 197. The dummy pattern 199 may be disposed to neighbor the data pad assistant 197 in the direction in which the data pad assistant 197 extends. That is, the dummy pattern 199 may neighbor the data pad assistant 197 substantially in the vertical direction. The dummy pattern 199 may have a quadrangular shape in the plane view. The present exemplary embodiment is not limited thereto, and the dummy pattern 199 may have various different shapes. For example, the dummy pattern 199 may have a polygonal shape such as a triangular shape or a pentagonal shape.

The dummy pattern 199 may be about greater than 20 μm wide. The dummy pattern 199 may be substantially generated to have the same width as the data pad assistant 197.

The dummy pattern 199 is separated from the data pad assistant 197 and it is floated. A plurality of dummy patterns 199 are disposed on the extended line of one data pad assistant 197, some of a plurality of dummy patterns 199 overlap the data pad 177, and the others do not overlap the data pad 177.

The dummy pattern 199 may be made of the same material as the pixel electrode 191 and the data pad assistant 197. That is, the dummy pattern 199 may be made of a transparent conductive material such as the indium-tin oxide (ITO) or the indium-zinc oxide (IZO). Adherence between the encapsulation layer 390 and the dummy pattern 199 is very low compared to adherence between the encapsulation layer 390 and the substrate 110, between the encapsulation layer 390 and the light blocking member 220, and between the encapsulation layer 390 and the roof layer 360. Therefore, when the encapsulation layer 390 is attached just over the dummy pattern 199 and the encapsulation layer 390 is immediately detached, most of the encapsulation layer 390 may be removed.

The common electrode 270, the liquid crystal layer, the second insulating layer 350, the third insulating layer 370, and the encapsulation layer 390 are shown to not be disposed on the peripheral area (PA) of the substrate 110. Further, the common electrode 270, the liquid crystal layer, the second insulating layer 350, the third insulating layer 370, and the encapsulation layer 390 may be disposed on part of the peripheral area (PA) of the substrate 110. In this instance, when the common electrode 270, the liquid crystal layer, the second insulating layer 350, the third insulating layer 370, and the encapsulation layer 390 are disposed on part of the peripheral area (PA) of the substrate 110, they do not cover the data pad portion (DP).

That is, the data pad portion (DP) may be exposed to the outside.

The data pad portion (DP) has been described, and the gate pad portion (GP) is also generated in the peripheral area of the display device according to an exemplary embodiment. Although not shown, the gate pad portion (GP) may include a gate pad and a gate pad assistant in a like manner of the data pad portion (DP). Further, a dummy pattern may be generated to neighbor a gate ohmic contact member.

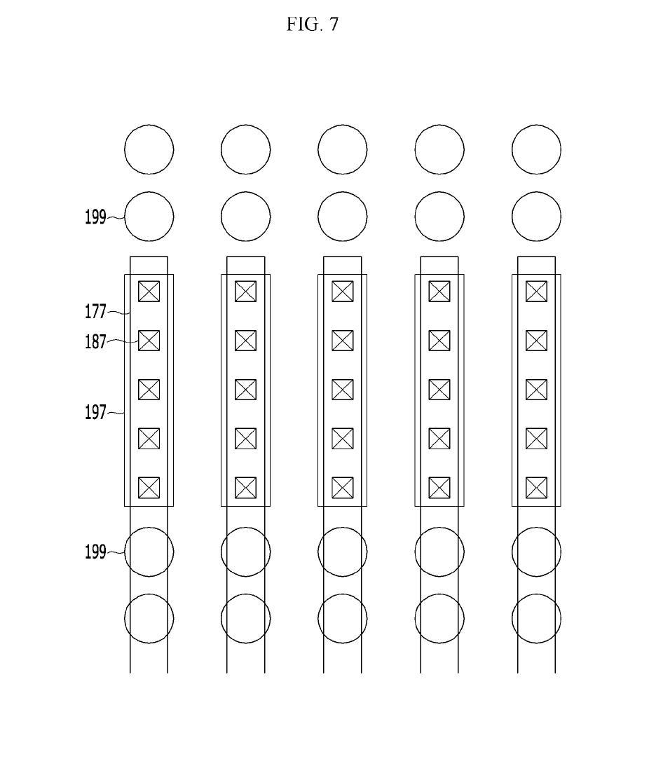

A display device according to an exemplary embodiment will now be described with reference to FIG. 7.

Many portions of the display device according to an exemplary embodiment shown in FIG. 7 correspond to the display device according to an exemplary embodiment shown in FIG. 1 to FIG. 6 so no description thereof will be provided. In the present exemplary embodiment, a shape of the dummy pattern in a plane view is different from the above-described exemplary embodiment, which will now be described.

FIG. 7 shows a top plan view of a peripheral area of a display device according to an exemplary embodiment.

In a like manner of the above-noted exemplary embodiment, the data pad 177 is disposed on the peripheral area (PA) of the substrate 110, and the data pad assistant 197 overlapping the data pad 177 and connected to the data pad 177 is provided. A dummy pattern 199 is disposed to neighbor the data pad assistant 197.

In the above-noted exemplary embodiment, the shape of the dummy pattern 199 in the plane view is quadrangular, and in the present exemplary embodiment, the shape of the dummy pattern 199 in the plane view is circular. The present exemplary embodiment is not limited thereto, and the shape of the dummy pattern 199 in the plane view may be oval.

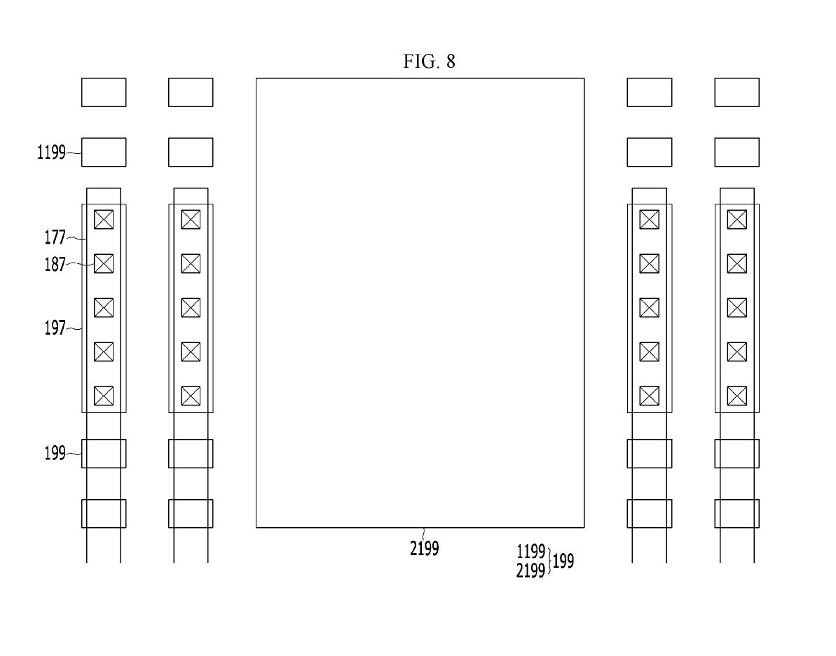

A display device according to an exemplary embodiment will now be described with reference to FIG. 8.

Many portions of the display device according to an exemplary embodiment shown in FIG. 8 correspond to the display device according to an exemplary embodiment shown in FIG. 1 to FIG. 6 so no description thereof will be provided. In the present exemplary embodiment, a dummy pattern is further provided between two neighboring pads, which is different from the previous exemplary embodiment, and will now be described.

FIG. 8 shows a top plan view of a peripheral area of a display device according to an exemplary embodiment.

In a like manner of the above-described exemplary embodiment, the data pad 177 is disposed on the peripheral area (PA) of the substrate 110, and a data pad assistant 197 overlapping the data pad 177 and connected to the data pad 177 is provided. Further, a dummy pattern 199 is disposed to neighbor the data pad assistant 197.

The dummy pattern 199 includes a first dummy pattern 1199 and a second dummy pattern 2199. The first dummy pattern 1199 may neighbor the data pad assistant 197 in the direction in which the data pad assistant 197 extends. That is, the first dummy pattern 1199 may neighbor the data pad assistant 197 substantially in the vertical direction. The second dummy pattern 2199 may neighbor the data pad assistant 197 in the direction perpendicular to the direction in which the data pad assistant 197 extends. That is, the second dummy pattern 2199 may neighbor the data pad assistant 197 substantially in the horizontal direction. A plurality of data pads 177 may be disposed on the peripheral area (PA) of the substrate 110, and the second dummy pattern 2199 may be disposed between two of a plurality of neighboring data pads 177.

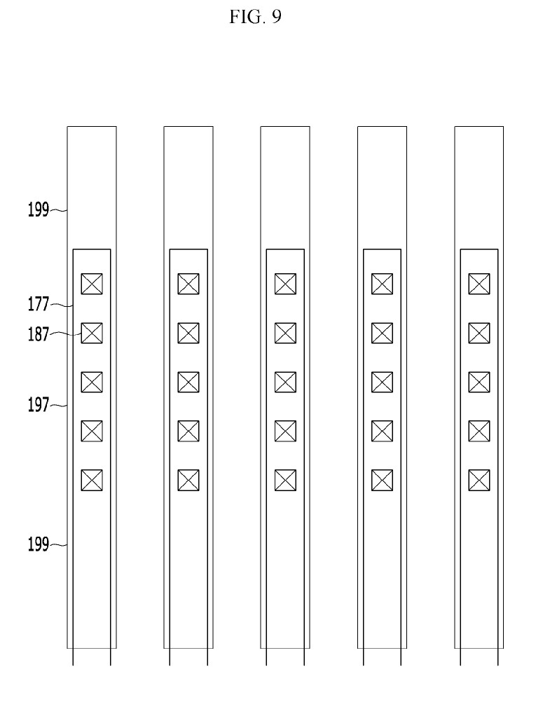

A display device according to an exemplary embodiment will now be described with reference to FIG. 9.

Many portions of the display device according to an exemplary embodiment shown in FIG. 9 correspond to the display device according to an exemplary embodiment shown in FIG. 1 to FIG. 6 so no description thereof will be provided. In the present exemplary embodiment, the dummy pattern is not floated, which is different from the previous exemplary embodiment and will now be described.

FIG. 9 shows a top plan view of a peripheral area of a display device according to an exemplary embodiment.

While the dummy pattern 199 is floated in the above-noted exemplary embodiment, the dummy pattern 199 according to the present exemplary embodiment is connected to the data pad assistant 197. That is, the data pad assistant 197 and the dummy pattern 199 are integrally formed. Therefore, a data signal may be applied to the dummy pattern 199. The dummy pattern 199 extends in the direction in which the data pad assistant 197 extends.

A method for manufacturing a display device according to an exemplary embodiment will now be described with reference to FIG. 10 to FIG. 25 and FIG. 1 to FIG. 6.

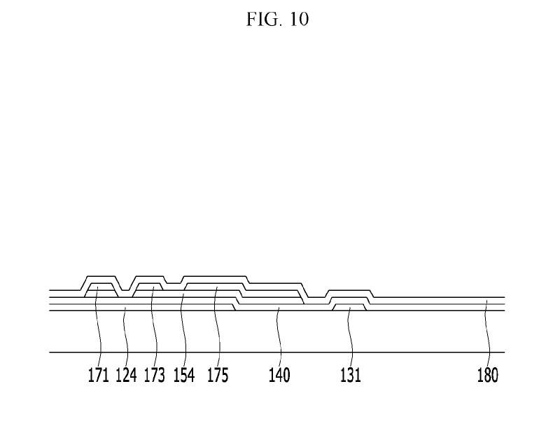

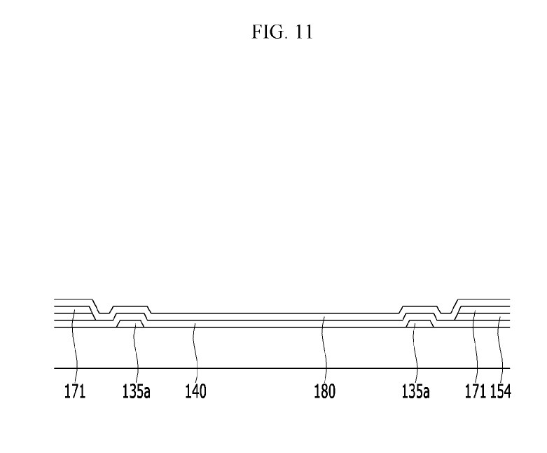

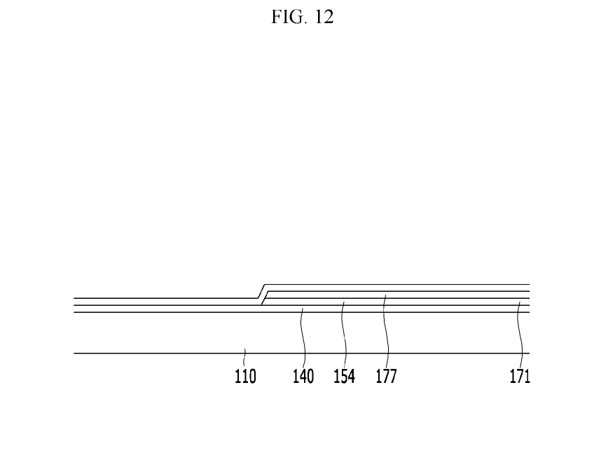

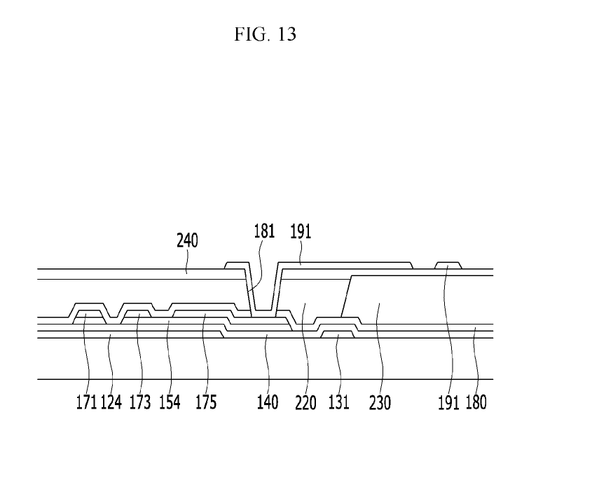

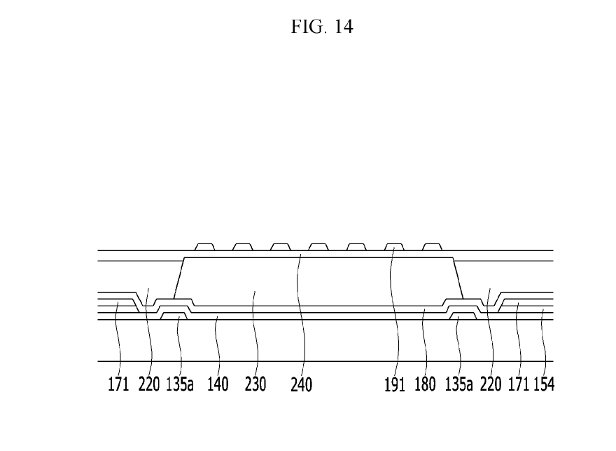

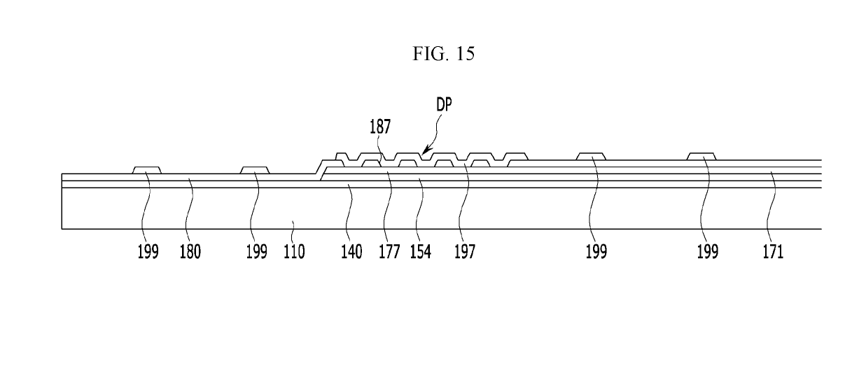

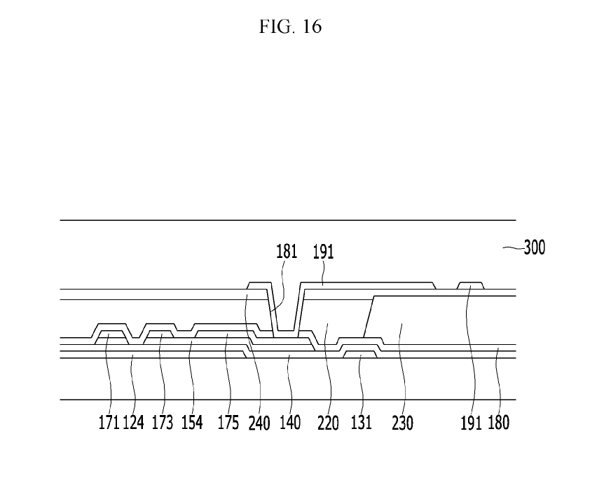

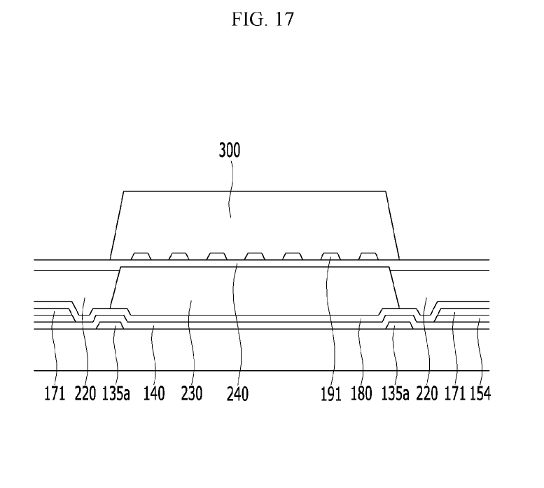

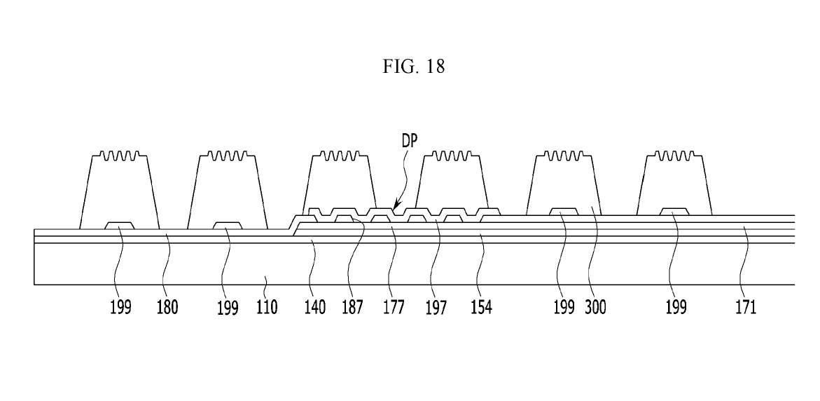

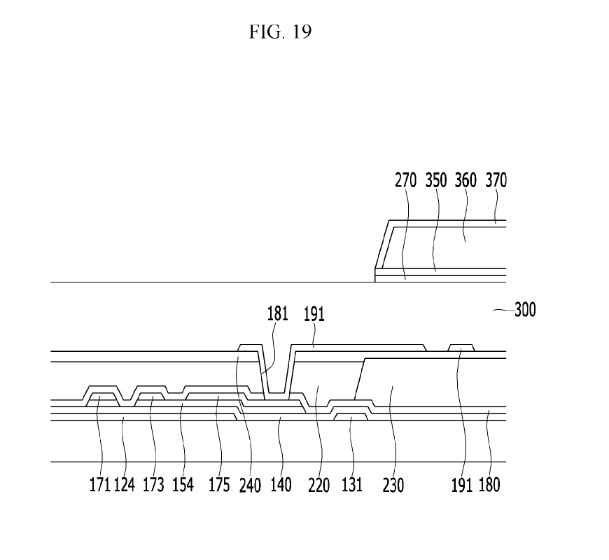

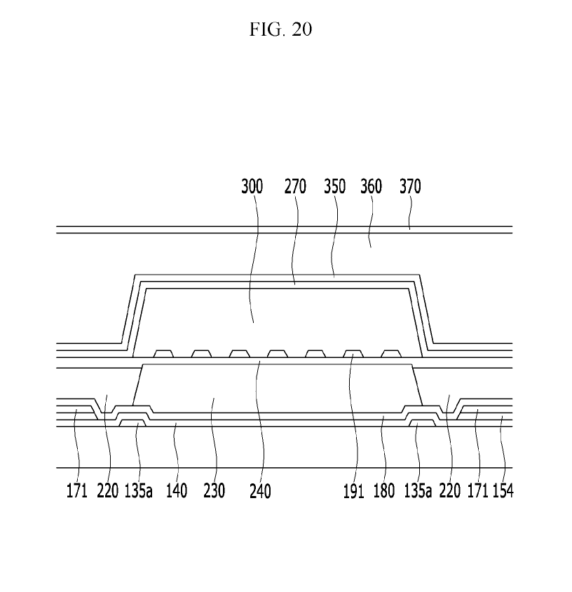

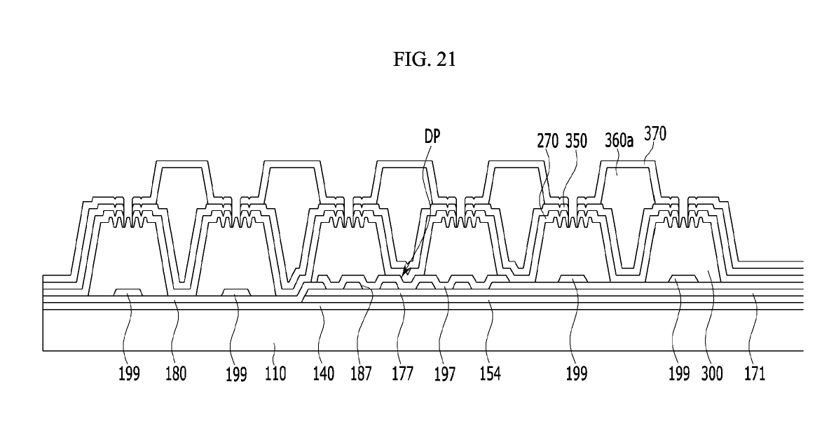

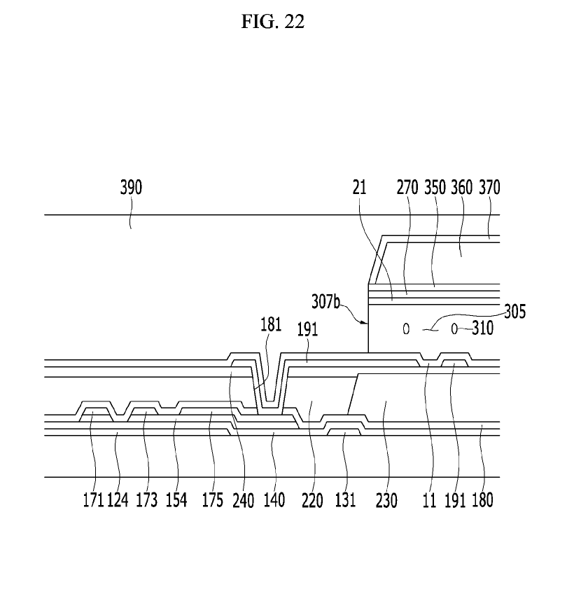

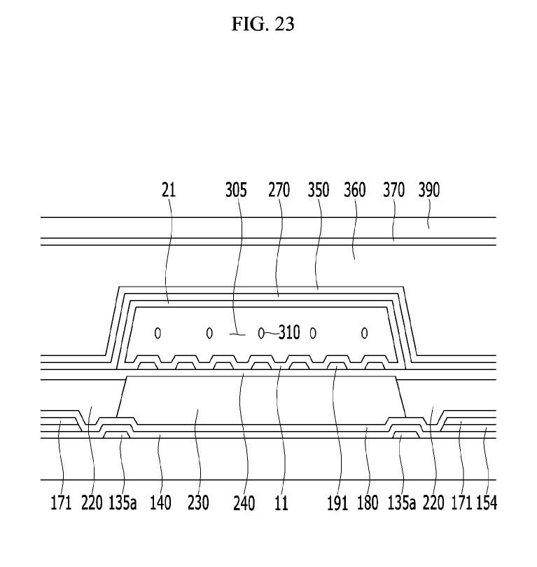

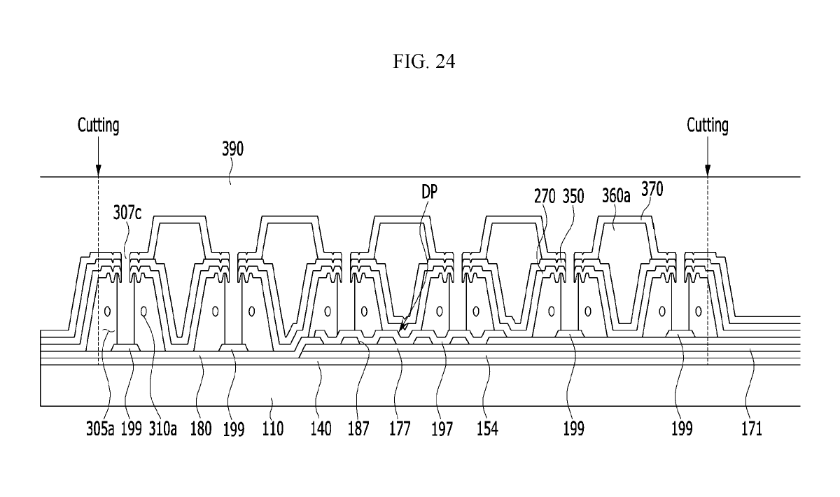

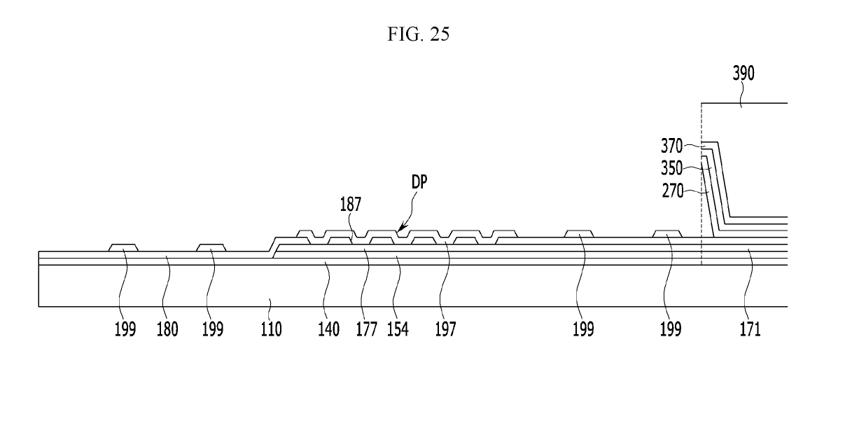

FIG. 10 to FIG. 25 show processing cross-sectional views of a method for manufacturing a display device according to an exemplary embodiment.

As shown in FIG. 10 to FIG. 12, a gate line 121 substantially extending in the horizontal direction and a gate electrode 124 protruding from the gate line 121 are generated on the substrate 110 made of glass or plastic.

When the gate line 121 is generated, storage electrodes 135a and 135b protruding from the reference voltage line 131 and the reference voltage line 131 may be generated so as to be separated from the gate line 121. The reference voltage line 131 extends in parallel to the gate line 121. The storage electrodes 135a and 135b include a pair of first storage electrodes 135a substantially perpendicularly extending with respect to the reference voltage line 131 and a second storage electrode 135b for connecting the one pair of first storage electrodes 135a. The reference voltage line 131 and the storage electrodes 135a and 135b may have a shape for surrounding the pixel electrode 191.

A gate insulating layer 140 generated by using an inorganic insulating material such as a silicon nitride (SiNx) or a silicon oxide (SiOx) is generated on the gate line 121, the gate electrode 124, the reference voltage line 131, and the storage electrodes 135a and 135b. The gate insulating layer 140 may be made of a single layer or multiple layers.

A semiconductor material such as amorphous silicon, polycrystalline silicon, or a metal oxide is deposited over the gate insulating layer 140. A metal material is deposited and the metal material and the semiconductor material are patterned to generate a semiconductor 154, a data line 171, a source electrode 173, a drain electrode 175, and a data pad 177. The metal material may be made of a single layer or multiple layers.

The semiconductor 154 is disposed on the gate electrode 124 and below the data line 171, the source electrode 173, the drain electrode 175, and the data pad 177. The semiconductor material and the metal material have been shown to be continuously deposited and simultaneously patterned, but the present inventive concept is not restricted thereto. The semiconductor material may be deposited and patterned to generate the semiconductor 154 in advance, and a metal material may be deposited and patterned to generate the data line 171. In this instance, the semiconductor 154 may not be provided below the data line 171 and the data pad 177.

The data line 171 substantially extends in the vertical direction to cross the gate line 121 and the reference voltage line 131. The source electrode 173 protrudes over the gate electrode 124 from the data line 171, and part of the drain electrode 175 is surrounded by the source electrode 173. The data line 171, the source electrode 173, and the drain electrode 175 are disposed in the display area (DA), and the data line 171 extends to the peripheral area (PA).

The data pad 177 is connected to the data line 171. The data pad 177 extends from an end portion of the data line 171. The end portion of the data line 171 is disposed in the peripheral area (PA), and the data pad 177 is disposed in the peripheral area (PA). The data pad 177 may be made of the same material as the data line 171, the source electrode 173, and the drain electrode 175, and may be disposed on the same layer thereof.

The gate electrode 124, the source electrode 173, and the drain electrode 175 configure a thin film transistor (TFT) Q with the semiconductor 154. The thin film transistor Q may function as a switching element for transmitting a data voltage of the data line 171. In this instance, a channel of the switching element is generated on a semiconductor 154 between the electrode 173 and the drain electrode 175.

A passivation layer 180 is generated on exposed portions of the data line 171, the source electrode 173, the drain electrode 175, and the semiconductor 154

The passivation layer 180 may be made of an organic insulating material or an inorganic insulating material, and may be made of a single layer or multiple layers. As shown in FIG. 13 to FIG. 15, a color filter 230 is generated over the passivation layer 180. The color filter 230 may be generated in each pixel and may not be generated on a border portion of the pixel. A plurality of color filters 230 allowing different wavelengths to pass through may be generated, and in this instance, color filters 230 of the same color may be generated in the column direction. When the color filters 230 of three colors are generated, the color filter 230 of a first color is generated, a mask shifts to generate the color filter 230 of a second color, and the mask shifts to generate the color filter 230 of a third color.

A light blocking member 220 is generated on the passivation layer 180 by using a light blocking material. The light blocking member 220 is disposed on the border portion of the pixel, and may overlap the gate line 121, the data line 171, and the thin film transistor Q to prevent light leakage. The present inventive concept is not limited thereto, and the light blocking member 220 may overlap the gate line 121 and the thin film transistor Q and may not overlap the data line 171.

A first insulating layer 240 is generated on the color filter 230 and the light blocking member 220. The first insulating layer 240 may be made of an organic insulating material and may function to planarize the upper sides of the color filter 230 and the light blocking member 220. The first insulating layer 240 may be generated as double layers by continuously depositing a layer of an organic insulating material and a layer of an inorganic insulating material.

The color filter 230, the light blocking member 220, and the first insulating layer 240 may not be disposed in the peripheral area (PA) of the substrate 110.

The first insulating layer 240, the light blocking member 220, and the passivation layer 180 may be patterned to generate a contact hole 181 for exposing at least part of the drain electrode 175 and a contact hole 187 for exposing at least part of the data pad 177.

A transparent conductive material such as an indium-tin oxide (ITO) or an indium-zinc oxide (IZO) is deposited on the first insulating layer 240 and is patterned to generate a pixel electrode 191. The pixel electrode 191 is connected to the drain electrode 175 through the contact hole 181. The pixel electrode 191 has a quadrangular shape, and may include a horizontal stem 193 and a vertical stem 192 crossing each other, and a fine branch 194 extending therefrom.

When the pixel electrode 191 is generated, a data pad assistant 197 and a dummy pattern 199 are generated. The data pad assistant 197 is connected to the data pad 177 through the contact hole 187. The dummy pattern 199 is disposed to neighbor the data pad assistant 197. The dummy pattern 199 may neighbor the data pad assistant 197 in the extending direction of the data pad assistant 197. That is, the dummy pattern 199 may neighbor the data pad assistant 197 substantially in the vertical direction. The dummy pattern 199 is separated from the data pad assistant 197 and is floated.

The data pad assistant 197 and the dummy pattern 199 may be generated with the same material as the pixel electrode 191 and may be disposed on the same layer. That is, the dummy pattern 199 may be made of a transparent conductive material such as an indium-tin oxide (ITO) or an indium-zinc oxide (IZO).

As shown in FIG. 16 to FIG. 18, a sacrificial layer 300 is generated on the pixel electrode 191, the first insulating layer 240, the data pad assistant 197, and the dummy pattern 199. The sacrificial layer 300 may be generated over the display area (DA) and the peripheral area (PA) of the substrate 110. The sacrificial layer 300 may overlap the pixel electrode 191 over the display area (DA) of the substrate 110. An upper side of the sacrificial layer 300 may be planarized over the display area (DA) of the substrate 110. The sacrificial layer 300 may overlap the data pad assistant 197 and the dummy pattern 199 over the peripheral area (PA) of the substrate 110. The upper side of the sacrificial layer 300 may have a shape of protrusions and depressions over the peripheral area (PA) of the substrate 110. That is, the upper side of the sacrificial layer 300 may not be planarized over the peripheral area (PA) of the substrate 110. A halftone mask or a slit mask may be used so that some region of the sacrificial layer 300 may be made planarized and another region thereof may be generated to have a shape of protrusions and depressions.

As shown in FIG. 19 to FIG. 21, a common electrode 270 is generated by depositing a transparent conductive material such as an indium-tin oxide (ITO) or an indium-zinc oxide (IZO) over the sacrificial layer 300.

A second insulating layer 350 may be generated over the common electrode 270 by using an inorganic insulating material such as a silicon nitride (SiNx) or a silicon oxide (SiOx).

The upper side of the sacrificial layer 300 has a shape of protrusions and depressions over the peripheral area (PA) of the substrate 110, so the upper sides of the common electrode 270 and the second insulating layer 350 disposed on the sacrificial layer 300 disposed on the peripheral area (PA) of the substrate 110 may respectively have a shape of protrusions and depressions.

An organic material is applied over the second insulating layer 350 and is patterned to generate a roof layer 360 over the display area (DA) of the substrate 110, and a partition wall 360a is generated over the peripheral area (PA) of the substrate 110. In this instance, the organic material on a portion overlapping the gate line 121 and the thin film transistor Q over the display area (DA) of the substrate 110 may be patterned so as to be removed. Hence, the roof layer 360 may have a shape substantially extending in the horizontal direction in the plane view. The organic material may be patterned to remain in the region between two neighboring sacrificial layers 300 over the peripheral area (PA) of the substrate 110. Accordingly, the partition wall 360a may cover a lateral side and an upper side of an edge of the sacrificial layer 300.

After the roof layer 360 and the partition wall 360a are generated, rays are irradiated to the roof layer 360 and the partition wall 360a to perform a curing process. After the curing process is performed, the roof layer 360 and the partition wall 360a become rigid and they may maintain their shapes while a predetermined space is generated below the roof layer 360 and the partition wall 360a.

The second insulating layer 350 and the common electrode 270 are patterned to remove a portion of the second insulating layer 350 and the common electrode 270 overlapping the gate line 121 and the thin film transistor Q over the display area (DA) of the substrate 110. Further, part of the second insulating layer 350 and the common electrode 270 disposed on the sacrificial layer 300 are removed over the peripheral area (PA) of the substrate 110.

An inorganic insulating material such as a silicon nitride (SiNx) or a silicon oxide (SiOx) may be deposited over the roof layer 360 and may be patterned to generate a third insulating layer 370. The upper side of the sacrificial layer 300 has a shape of protrusions and depressions over the peripheral area (PA) of the substrate 110 so the third insulating layer 370 disposed on the sacrificial layer 300 may have a shape of protrusions and depressions over the peripheral area (PA) of the substrate 110.

The inorganic insulating material on the portion overlapping the gate line 121 and the thin film transistor Q may be patterned so as to be removed over the display area (DA) of the substrate 110. Part of the second insulating layer 350 and the common electrode 270 disposed on the sacrificial layer 300 are removed over the peripheral area (PA) of the substrate 110. The third insulating layer 370 covers the upper side of the roof layer 360, and it may cover a lateral side of the roof layer 360. Further, the third insulating layer 370 may cover the upper side and the lateral side of the partition wall 360a.

When the roof layer 360, the second insulating layer 350, the common electrode 270, and the third insulating layer 370 are patterned, part of the sacrificial layer 300 is exposed.

When the sacrificial layer 300 is totally removed by supplying a development solution or a stripper solution to the exposed sacrificial layer 300 or by using an ashing process, a microcavity 305 and a dummy microcavity 305a are generated in the place where the sacrificial layer 300 was provided as shown in FIG. 22 to FIG. 24. The microcavity 305 is disposed on the display area (DA) of the substrate 110, and the dummy microcavity 305a is disposed on the peripheral area (PA) of the substrate 110.

The pixel electrode 191 is separated from the roof layer 360 with the microcavity 305 therebetween over the display area (DA) of the substrate 110. The data pad assistant 197 is separated from the second insulating layer 350 with the dummy microcavity 305a therebetween over the peripheral area (PA) of the substrate 110. The roof layer 360 covers part of the upper side and the lateral side of the microcavity 305. The second insulating layer 350 covers part of the upper side and the lateral side of the dummy microcavity 305.

The microcavity 305 is exposed through the portion from which the common electrode 270, the second insulating layer 350, the roof layer 360, and the third insulating layer 370 are removed over the display area (DA) of the substrate 110, and portions where the microcavity 305 is exposed will be referred to as injection holes 307a and 307b. Two injection holes 307a and 307b may be generated in one microcavity 305, and for example, a first injection hole 307a for exposing a lateral side of a first edge of the microcavity 305 and a second injection hole 307b for exposing a lateral side of a second edge of the microcavity 305 may be generated. The first edge faces the second edge, and for example, the first edge may be an upper edge of the microcavity 305 and the second edge may be a lower edge of the microcavity 305 in a plane view. The dummy microcavity 305a is exposed outside through the portion from which the common electrode 270, the second insulating layer 350, the partition wall 360a, and the third insulating layer 370 are removed over the peripheral area (PA) of the substrate 110, and a portion where the dummy microcavity 305a is exposed will be referred to as an injection hole 307c. The injection hole 307c may expose the upper side of the dummy microcavity 305a. The injection hole 307c overlaps the data pad assistant 197 and the dummy pattern 199.

When an aligning agent including an aligning material is deposited on the display area (DA) of the substrate 110 according to a spin coating method or an Inkjet method, the aligning agent is injected into the microcavity 305 through the injection holes 307a and 307b. When the curing process is performed after the aligning agent is injected into the microcavity 305, the liquid component is vaporized and the aligning material remains on a wall in the microcavity 305.

Therefore, the first alignment layer 11 may be generated over the pixel electrode 191, and the second alignment layer 21 may be generated below the common electrode 270. The first alignment layer 11 and the second alignment layer 21 are generated to face each other with a microcavity 305 therebetween, and are generated to be connected to each other on a lateral wall of the edge of the microcavity 305. In this instance, the first and second alignment layers 11 and 21 may be aligned in a direction perpendicular to the substrate 110 except the lateral side of the microcavity 305.

When a liquid crystal material is deposited on the display area (DA) and the peripheral area (PA) of the substrate 110 according to the Inkjet method or the dispensing method, the liquid crystal material is injected into the microcavity 305 through the injection holes 307a and 307b by a capillary force and is injected into the dummy microcavity 305a through the injection hole 307c. Therefore, a liquid crystal layer of liquid crystal molecules 310 is generated in the microcavity 305, and a liquid crystal layer of liquid crystal molecules 310a is generated in the dummy microcavity 305a.

An encapsulation layer 390 is generated over the third insulating layer 370 by using a material that does not react with the liquid crystal molecules 310. The encapsulation layer 390 is generated to cover the injection holes 307a and 307b to seal the microcavity 305 so that the liquid crystal molecules 310 disposed in the microcavity 305 may not come out. Further, the encapsulation layer 390 is generated to cover the injection hole 307c to seal the dummy microcavity 305a so that the liquid crystal molecules 310a disposed in the dummy microcavity 305a may not come out. In this instance, the encapsulation layer 390 may permeate into the dummy microcavity 305a during the process for generating an encapsulation layer 390. The encapsulation layer 390 may apply pressure to the liquid crystal molecules 310a disposed below the injection hole 307c to push them. Therefore, the encapsulation layer 390 may be generated below the injection hole 307c. The injection hole 307c overlaps the data pad assistant 197 and the dummy pattern 199, and the encapsulation layer 390 having permeated into the dummy microcavity 305a may be disposed directly on the data pad assistant 197 and the dummy pattern 199.

Laser beams irradiate the encapsulation layer 390 disposed on the border between the display area (DA) and the peripheral area (PA) of the substrate 110, and the laser beams irradiate the encapsulation layer 390 disposed on the edge of the peripheral area (PA) to cut the encapsulation layer 390, the third insulating layer 370 disposed below the same, the second insulating layer 350, and the common electrode 270. The laser beams have been described to be used in the process for cutting an encapsulation layer 390, to which the present exemplary embodiment is not limited, and the cutting process may be performed by another method.

When the encapsulation layer 390, the third insulating layer 370, the second insulating layer 350, and the common electrode 270 provided among positions of irradiation of laser beams are separated from the substrate 110, as shown in FIG. 25, the liquid crystal layers provided in the dummy microcavity 305a and the dummy microcavity 305a are removed. As described above, the encapsulation layer 390 may permeate into the dummy microcavity 305a, and when adherence of the encapsulation layer 390 to the layer inside the dummy microcavity 305a is high, the encapsulation layer 390 may not be removed but may remain. In the present exemplary embodiment, when the data pad assistant 197 and the dummy pattern 199 are provided below the injection hole 307c and the encapsulation layer 390 permeates into the dummy microcavity 305a, it contacts the data pad assistant 197 and the dummy pattern 199. The data pad assistant 197 and the dummy pattern 199 are made of a transparent conductive material such as an indium-tin oxide (ITO) or an indium-zinc oxide (IZO), and the material has relatively low adherence with the encapsulation layer 390. For example, the adherence between the encapsulation layer 390 and one of the substrate 110, the light blocking member 220, and the passivation layer 180 is greater than the adherence between the transparent conductive material and the encapsulation layer 390. Therefore, during the process for removing the encapsulation layer 390, the encapsulation layer 390 may be easily separated from the data pad assistant 197 and the dummy pattern 199.

The data pad 177, the data pad assistant 197, and the dummy pattern 199 remain over the peripheral area (PA) of the substrate 110. In this instance, the data pad assistant 197 and the dummy pattern 199 are exposed to the outside.

The edge of the peripheral area (PA) of the substrate 110 is polished to remove the encapsulation layer 390, the third insulating layer 370, the second insulating layer 350, and the common electrode 270 remaining on the edge of the peripheral area (PA) of the substrate 110.

Although not shown, a polarizer may further be attached to upper/lower sides of the display device. The polarizer may include a first polarizer and a second polarizer. The first polarizer may be attached to the lower side of the substrate 110, and the second polarizer may be attached over the encapsulation layer 390.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A display device comprising:
a substrate including a display area and a peripheral area;
a thin film transistor disposed on the display area of the substrate;
a first electrode connected to the thin film transistor;
a roof layer disposed on the first electrode and separated from the first electrode with a microcavity therebetween;
an encapsulation layer disposed on the roof layer;
a pad disposed on the peripheral area of the substrate;
a pad assistant overlapping the pad and connected to the pad; and
a dummy pattern neighboring the pad assistant and made of a transparent conductive material.

2. The display device of claim 1, wherein
the dummy pattern is disposed on a same layer as the pad assistant and the first electrode, and is made of a same material.

3. The display device of claim 1, wherein
the dummy pattern is made of an indium-tin oxide or an indium-zinc oxide.

4. The display device of claim 1, wherein
the pad and the pad assistant extend in a first direction, and
the dummy pattern includes a first dummy pattern neighboring the pad assistant in the first direction.

5. The display device of claim 4, wherein
the dummy pattern is equal to or greater than 20 μm wide.

6. The display device of claim 4, wherein
the dummy pattern is floated.

7. The display device of claim 4, wherein
the dummy pattern is circular or polygonal in a plane view.

8. The display device of claim 4, wherein
the dummy pattern further includes a second dummy pattern neighboring the pad assistant in a second direction that is perpendicular to the first direction.

9. The display device of claim 8, wherein
a plurality of pads are disposed over the peripheral area of the substrate, and the second dummy pattern is disposed between two neighboring pads from among the plurality of pads.

10. The display device of claim 1, wherein
the pad assistant and the dummy pattern are integrally formed.

11. A method for manufacturing a display device, comprising:
generating a thin film transistor on a display area of a substrate including the display area and a peripheral area;
generating a pad on the peripheral area of the substrate;
generating a first electrode to be connected to the thin film transistor;
generating a pad assistant to be connected to the pad;
generating a dummy pattern with a transparent conductive material to neighbor the pad assistant;
generating a sacrificial layer on the first electrode, the pad assistant, and the dummy pattern;
generating an insulating layer on the sacrificial layer;
generating a roof layer on the insulating layer;
generating a microcavity between the first electrode and the insulating layer by removing the sacrificial layer, and generating a dummy microcavity between the pad assistant and the insulating layer and between the dummy pattern and the insulating layer;
generating an encapsulation layer on the roof layer; and
removing the encapsulation layer and the insulating layer disposed on the peripheral area of the substrate.

12. The method of claim 11, further comprising
generating an injection hole for exposing at least part of the dummy microcavity by patterning the insulating layer,
wherein the injection hole overlaps the pad assistant and the dummy pattern.

13. The method of claim 11, wherein
the dummy pattern is disposed in a same layer as the pad assistant and the first electrode and is made of a same material, and
the dummy pattern is made of an indium-tin oxide or an indium-zinc oxide.

14. The method of claim 11, wherein
the pad and the pad assistant extend in a first direction, and
the dummy pattern includes a first dummy pattern neighboring the pad assistant in the first direction.

15. The method of claim 14, wherein
the dummy pattern is equal to or greater than 20 μm wide.

16. The method of claim 14, wherein
the dummy pattern is floated.

17. The method of claim 14, wherein
the dummy pattern is circular or polygonal in a plane view.

18. The method of claim 14, wherein
the dummy pattern further includes a second dummy pattern neighboring the pad assistant in a second direction that is perpendicular to the first direction.

19. The method of claim 18, wherein
a plurality of pads are disposed on the peripheral area of the substrate, and the second dummy pattern is disposed between two neighboring pads from among the plurality of pads.

20. The method of claim 11, wherein
the pad assistant and the dummy pattern are integrally formed.
